(19) United States
(12) Patent Application Publication
(10) Pub. No.: US 2019/0181614 A1
(43) Pub. Date: Jun. 13, 2019

(54) LASER RADAR DEVICE

(71) Applicant: HON HAI PRECISION INDUSTRY CO., LTD., New Taipei (TW)

(72) Inventor: PO-YU LIN, New Taipei (TW)

(21) Appl. No.: 15/869,604

(22) Filed: Jan. 12, 2018

(30) Foreign Application Priority Data
Dec. 7, 2017 (CN) 201711285083.3

(51) Int. Cl. H01S 5/183; H01S 5/42; H01S 5/343; H01S 5/042; H01S 5/34

(52) U.S. Cl. CPC H01S 5/18361; H01S 5/423; H01S 5/3422; H01S 5/042; H01S 5/3412; H01S 5/34306

(57) ABSTRACT

A laser radar device includes a transmitter, a receiver, and an optical coupler. The optical coupler includes an incident surface, an emergent surface, and a reflective surface. At least one convergent lens is positioned at the incident surface. The convergent lens is aligned with the transmitter and the receiver. At least one collimating lens is positioned at the emergent surface. The at least one collimating lens corresponds to the at least one convergent lens. An angle between the reflective surface and the incident surface is equal to an angle between the reflective surface and the emergent surface.

### FIELD

The subject matter relates to a laser radar device, especially relates to a laser radar ranging device based on vertical cavity surface emitting laser (VCSEL).

### BACKGROUND

Laser radar devices can be used for distance detection. Such a laser radar device may include a laser emitter, a detector, and a plurality of lenses. The laser emitter and the detector are usually separated. The lenses are independently manufactured, which can cause performance deviation. Furthermore, mechanical components are required to mount the plurality of lenses during assembly, which is cumbersome and further causes deviation. Thus, improvement in the art is needed.

### BRIEF DESCRIPTION OF THE DRAWINGS

Implementations of the present disclosure will now be described, by way of example only, with reference to the attached figures, wherein:

FIG. 1 is a diagram of a laser radar device, in accordance with an exemplary embodiment of the present disclosure.

FIG. 2 is an exploded view of the laser radar device of FIG. 1.

FIG. 3 is a diagram of an optical coupling device included in the laser radar device of FIG. 2.

FIG. 4 is a cross-sectional view taken along line IV-IV of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein can be practiced without these specific details.

In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

Definitions that apply throughout this disclosure will now be presented.

The term “substantially” is defined to be essentially conforming to the particular dimension, shape, or other feature that the term modifies, such that the component need not be exact. For example, “substantially rectangular” means that the object resembles a rectangle, but can have one or more deviations from a true rectangle.

The term “comprising,” when utilized, means “including, but not necessarily limited to”; it specifically indicates open-ended inclusion or membership in the so-described combination, assembly, series, and the like.

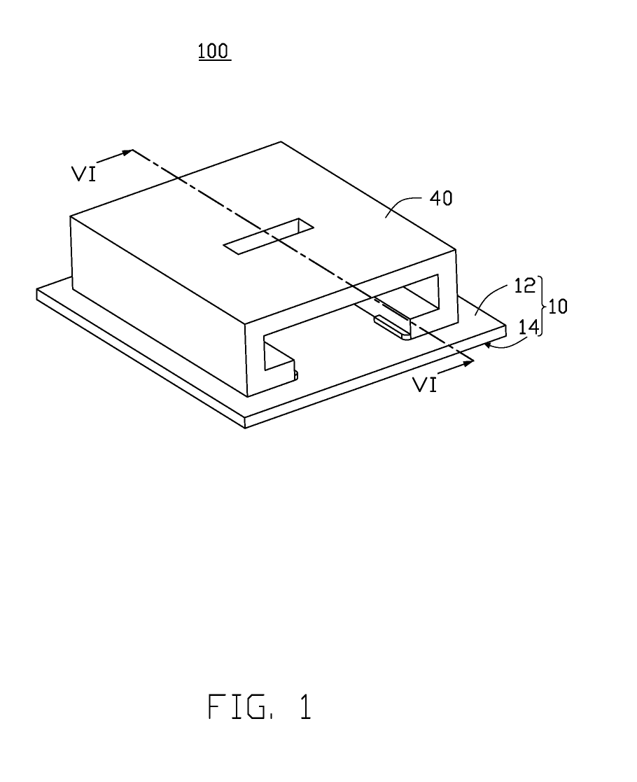

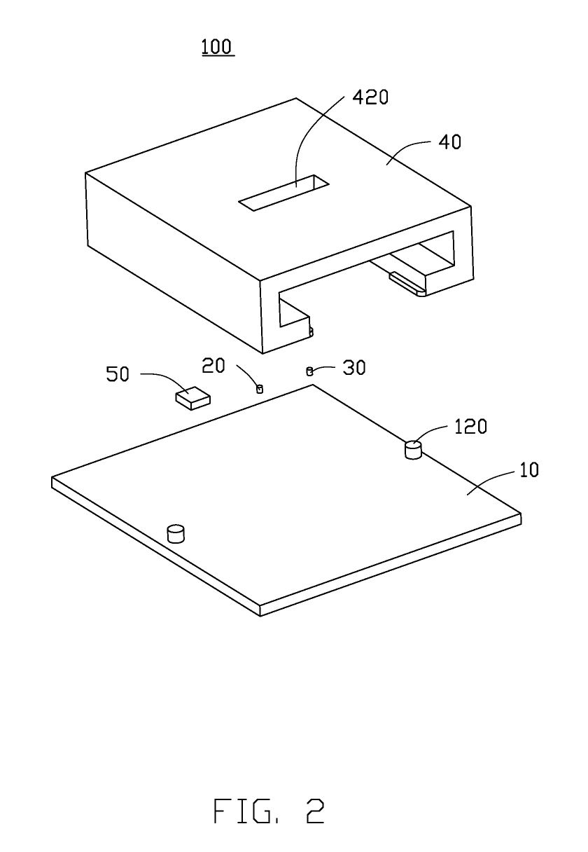

Referring to FIG. 1 and FIG. 2, a laser radar device 100 comprises a printed circuit board 10, a transmitter 20, a receiver 30, an optical coupler 40, and a processor 50.

The printed circuit board 10 comprises a first surface 12 and a second surface 14. The first surface 12 and the second surface 14 are opposite sides of the printed circuit board 10. The first surface 12 is parallel to the second surface 14.

The transmitter 20 and the receiver 30 are mounted on the first surface 12. The transmitter 20 and the receiver 30 are spaced apart from each other. Both the transmitter 20 and the receiver 30 are electrically connected to the printed circuit board 10. In the exemplary embodiment, the transmitter 20 is a vertical cavity surface emitting laser (VCSEL) for emitting laser light. The receiver 30 is configured to receive light which is reflected by an object (not shown).

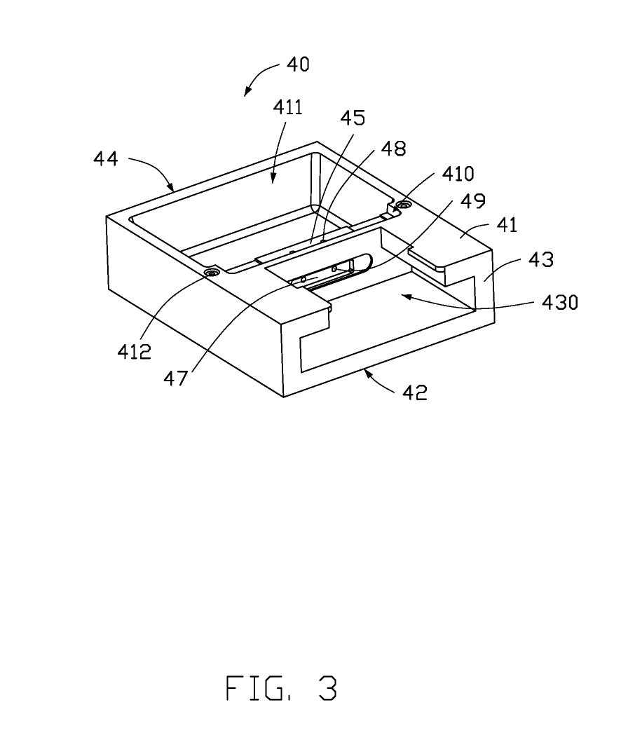

Referring to FIG. 1 and FIG. 3, the optical coupler 40 is mounted on the first surface 12. The optical coupler 40 is a substantially rectangular. The optical coupler 40 comprises a lower surface 41, an upper surface 42, a front surface 43, and a rear surface 44. The lower surface 41 and the upper surface 42 are opposite and parallel to each other. The front surface 43 and the rear surface 44 are opposite and parallel to each other. The front surface 43 and the rear surface 44 are perpendicularly connected to the lower surface 41 and the upper surface 42. The lower surface 41 is mounted on the first surface 12. A first recess 410 is defined in the lower surface 41. A bottom surface of the first recess 410 is parallel to the lower surface 41 and serves as an incident surface 45 of the optical coupler 40. A second recess 420 is defined in the upper surface 42. A bottom surface of the second recess 420 is oblique to the upper surface 42 and serves as a reflective surface 46 of the optical coupler 40. A third recess 430 is defined in the front surface 43. A bottom surface of the third recess 430 is parallel to the front surface 43 and serves as an emergent surface 47 of the optical coupler 40. The emergent surface 47 is corresponding to the incident surface 45. An angle between the reflective surface 46 and the incident surface 45 is equal to an angle between the reflective surface 46 and the emergent surface 47. In the exemplary embodiment, the angle between the reflective surface 46 and the incident surface 45 is equal to 45 degrees. A fourth recess 411 is defined in the lower surface 41. The fourth groove 411 is in air communication with the first groove 410. In the exemplary embodiment, the fourth groove 411 is a substantially trapezoidal. A depth of the fourth groove 411 is greater than a depth of the first groove 410. The processor 50 is received in the fourth recess 411.

Two convergent lenses 48 are disposed on the incident surface 45. One convergent lens 48 diverges the light emitted by the transmitter 20 and the other lens 48 converges and condenses the incoming light reflected by the object. The two convergent lenses 48 have a same shape and size, and are respectively aligned with the transmitter 20 and the receiver 30.

Two collimating lenses 49 are disposed on the emergent surface 47. One collimating lens 48 is configured to collimate light from the optical coupler 40, and the other lens 49 collimates light entering into the optical coupler 40. Two collimating lenses 49 correspond to the two convergent lenses 48. The two collimating lenses 49 have a same shape and size.

In the exemplary embodiment, the convergent lenses 48 and the collimating lenses 49 are integrally formed with the optical coupler 40.

The processor 50 is disposed on the first surface 12 and electrically connected to the printed circuit board 10. The processor 50 is configured to control the transmitter 20 to emit laser light, and determines the distance between the laser radar device 100 and an object, orientation of the object, and/or size of the object, according to the reflected light from the object.

When assembled, the transmitter 20, the receiver 30, and the processor 50 are first disposed on the first surface 12. Then, the optical coupler 40 is disposed on the first surface 12 and covers the transmitter 20 and the receiver 30. At this time, the incident surface 45 is opposite to the first surface 12. One convergent lens 48 is aligned with each of the transmitter 20 and the receiver 30. Then, a peripheral portion of the optical coupler 40, which faces the first surface 12, is pasted with adhesive to mount the optical coupler 40 on the first surface 12, thereby completing the assembly of the laser radar device 100.

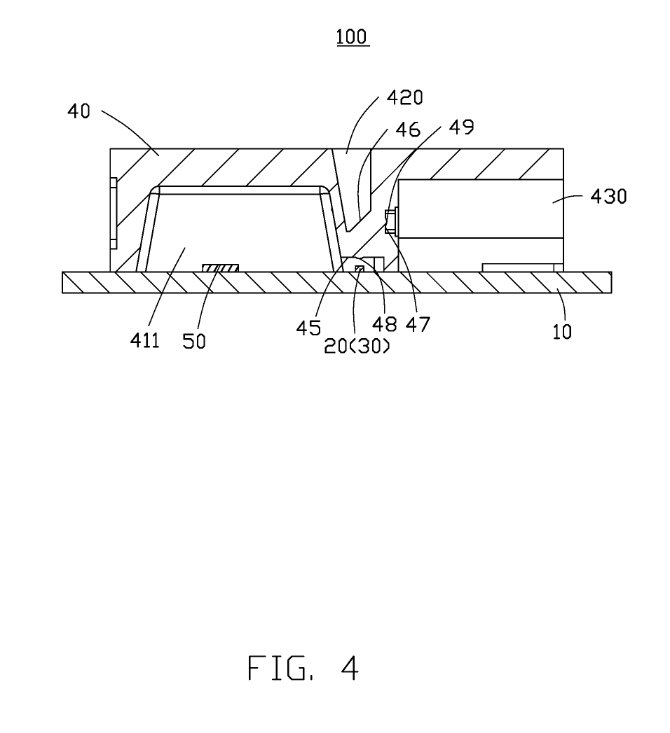

Referring to the FIG. 4, in operation, the light emitted by the transmitter 20 enters the optical coupler 40 from the incident surface 46, and the light path the transmitter 20 is changed by the reflective surface 46 and is emitted towards the object through a collimating lens 49. Then, the light reflected by the object enters the optical coupler 40 from the emergent surface 47, the light path is changed by the reflection surface 46 and is emitted from the incident surface 45, and finally the light is transmitted to the receiver 30. The receiver 30 transmits the optical signal to the processor 50.

In other exemplary embodiments, there may be only one convergent lens 48 and one collimating lens 49. A transmitter 20 and a receiver 30 can be simultaneously aligned with a convergent lens 48.

The number of the transmitter 20 and the receiver 30 is not limited to one, and the number of the convergent lens 48 or the collimating lens 49 is not limited to two, and may be changed according to need. For example, the transmitter 20 and the receiver 30 can also be four, six, or eight in number, provided that the total number of the transmitters 20 and the receivers 30 is the same as the total number of the convergent lenses 48 and the number of the collimating lenses 49.

In other exemplary embodiments, two positioning pins 120 are disposed on two opposite ends of the first surface 12. Two positioning holes 412 are defined in the lower surface 41. The two positioning holes 412 engage with the two positioning pins 120 to position the optical coupler 40 to the printed circuit board 10, and to align the convergent lens 48 to the transmitter 20 and the receiver 30.

In the exemplary embodiment, the laser radar device 100, the convergent lens 48, and the collimating lens 49 are disposed on the optical coupler 40, and the assembly between the transmitter 20, the receiver 30 and the convergent lens 48 can be completed in a single installation process, thereby improving installation accuracy and reducing errors during assembly.

The embodiments shown and described above are only examples. Many other details are found in the art. Therefore, many such details are neither shown nor described. Even though numerous characteristics and advantages of the present disclosure have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A laser radar device comprising:
a transmitter;
a receiver; and
an optical coupler,
wherein the optical coupler comprises an incident surface, an emergent surface, and a reflective surface, at least one convergent lens is positioned at the incident surface, the convergent lens is aligned with the transmitter and the receiver, at least one collimating lens is positioned at the emergent surface, the at least one collimating lens corresponds to the at least one convergent lens, and an angle between the reflective surface and the incident surface is equal to an angle between the reflective surface and the emergent surface.

2. The laser radar device of claim 1, wherein the angle between the reflective surface and the incident surface is 45 degrees.

3. The laser radar device of claim 1, wherein two convergent lenses are disposed on the incident surface, and the two convergent lenses are respectively aligned with the transmitter and the receiver.

4. The laser radar device of claim 3, wherein two collimating lenses are disposed on the emergent surface, and the two collimating lenses correspond to the two convergent lenses.

5. The laser radar device of claim 1, wherein the transmitter is a vertical cavity surface emitting laser.

6. The laser radar device of claim 1, wherein the convergent lenses and the collimating lenses are integrally formed with the optical coupler.

7. The laser radar device of claim 1 further comprising a printed circuit board, wherein the transmitter and the receiver are mounted on the circuit board.

8. The laser radar device of claim 7 wherein the optical coupler is mounted on the printed circuit board, and covers the transmitter and the receiver.

9. The laser radar device of claim 8, wherein the optical coupler is mounted on the printed circuit board by adhesive.

10. The laser radar device of claim 7, wherein two positioning pins are disposed on two opposite ends of the printed circuit board, two positioning holes are disposed on the optical coupler, and the two positioning pins are received in the two positioning holes.
